(19) United States
(12) Patent Application Publication
(10) Pub. No.: US 2024/0063148 A1
(43) Pub. Date: Feb. 22, 2024

(54) DEEP TRENCH CAPACITOR BRIDGE FOR MULTI-CHIP PACKAGE

(71) Applicant: Intel Corporation, Santa Clara, CA (US)

(72) Inventors: Loke Yip FOO, Bayan Lepas (MY); Teong Guan YEW, Batu Maung (MY); Bok Eng CHEAH, Gelugor (MY)

(21) Appl. No.: 17/889,395

(22) Filed: Aug. 17, 2022

(51) Int. Cl. H01L 23/64; H01L 23/538; H01L 21/48

(52) U.S. Cl. CPC H01L 23/642; H01L 23/5381; H01L 23/5386; H01L 21/4846

(57) ABSTRACT

A device is provided, including a bridge substrate and a redistribution layer on a top surface of the bridge substrate. The bridge substrate may include a plurality of trenches extending vertically into the bridge substrate from a bottom surface of the bridge substrate, wherein each of the plurality of trenches may include a conductive filling; a conductive layer partially surrounding the plurality of trenches and separated from the plurality of trenches by a dielectric layer; a plurality of first contact pads under the bottom surface of the bridge substrate and coupled to the conductive layer; and a plurality of second contact pads under the bottom surface of the bridge substrate and coupled to the conductive fillings of the plurality of trenches.

### BACKGROUND

In power delivery network (PDN) design, decoupling capacitors may be added to improve the PDN impedance and performance, especially for devices with very tight voltage constraint while having fast and big transient current. For embedded multi-die interconnect bridge (EMIB) based interface solutions, providing a low impedance connection to die side capacitance will be challenging when the EMIB interface is deep inside the die edge.

Existing solutions in mitigating power integrity for a multi-chip package (MCP) with EMIB include embedded package capacitor, package land-side capacitor (LSC) and/or package die side capacitor (DSC) designs. For DSC design, additional package surface area is required to implement DSC, which may lead to increased package form factor and costs. In addition, package substrate layer count may be increased to effectively connect the inner EMIB interfacing power domain to the DSC at the edge of the package. For LSC design, increased ball grid array (BGA) cavity keep-out zone (KOZ) for LSC component placement may lead to BGA input/output (TO) density trade-off and/or package form-factor expansion.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a cross-sectional view of a semiconductor device according to an aspect of the present disclosure.

FIG. 2 shows a cross-sectional view of a semiconductor device according to another aspect of the present disclosure.

FIG. 3A shows a cross-sectional view of a semiconductor device according to a further aspect of the present disclosure.

FIG. 3B shows a top view layout of the semiconductor device according to the aspect as shown in FIG. 3A.

FIG. 4 shows a flow chart illustrating a method of forming a semiconductor device according to an aspect of the present disclosure.

FIGS. 5A through 5G show cross-sectional views directed to an exemplary process flow for a method of making a semiconductor device according to an aspect of the present disclosure.

FIG. 6 shows a flow chart illustrating a method of forming a semiconductor device according to a further aspect of the present disclosure.

FIG. 7 shows an illustration of a computing device that includes a semiconductor device according to a further aspect of the present disclosure.

### DETAILED DESCRIPTION

The following detailed description refers to the accompanying drawings that show,

by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure introduces a bridge with deep trench capacitors (DTC) to enable shorter decoupling capacitance connection for improved power integrity in multi-chip package applications.

Advantages of the present disclosure may include improved power integrity through shorter interconnects between a silicon bridge deep trench capacitor (DTC) and power domains of an inter-chip interface, e.g., multi-die fabric interconnects (MDFI) interface. Reduced power delivery network impedance (ZPDN) and higher decoupling capacitance density may be achieved, compared to a metal-insulator-metal capacitor (MIMCAP) solution, e.g., up-to 400 nF/mm² vs 86 nF/mm².

Further advantages of the present disclosure may include device miniaturization through minimized package real-estate keep-out-zone requirement for the placement of decoupling capacitor components.

In all aspects, the present disclosure generally relates to a device that may include a bridge substrate, and a redistribution layer on a top surface of the bridge substrate. The bridge substrate may include a plurality of trenches extending vertically into the bridge substrate from a bottom surface of the bridge substrate, wherein each trench of the plurality of trenches may include a conductive filling. The bridge substrate may further include a conductive layer partially surrounding the plurality of trenches and separated from the plurality of trenches by a dielectric layer, a plurality of first contact pads under the bottom surface of the bridge substrate and coupled to the conductive layer, and a plurality of second contact pads under the bottom surface of the bridge substrate and coupled to the conductive fillings of the plurality of trenches.

The present disclosure generally relates to a method of forming a device. The method may include providing a bridge substrate and a redistribution layer under a bottom surface of the bridge substrate; forming a plurality of intermediate trenches vertically extending into the bridge substrate from a top surface of the bridge substrate; forming a conductive layer on inner walls of the plurality of intermediate trenches, and forming a dielectric layer on the conductive layer; forming conductive fillings into the plurality of intermediate trenches, wherein the conductive fillings are on the dielectric layer; and forming a plurality of first contact pads and a plurality of second contact pads on the top surface of the bridge substrate, wherein the plurality of first contact pads are coupled to the conductive layer, and wherein the plurality of second contact pads are coupled to the conductive fillings in the plurality of intermediate trenches.

The present disclosure generally relates to a semiconductor package. The semiconductor package may include a package substrate, a bridge at least partially embedded in the package substrate, a first die and a second die on the package substrate. The bridge may include a bridge substrate, and a redistribution layer on a top surface of the bridge substrate. The bridge substrate may include a plurality of trenches extending vertically into the bridge substrate from a bottom surface of the bridge substrate, wherein each trench of the plurality of trenches may include a conductive filling. The bridge substrate may further include a conductive layer partially surrounding the plurality of trenches and separated from the plurality of trenches by a dielectric layer, a plurality of first contact pads under the bottom surface of the bridge substrate and coupled to the conductive layer, and a plurality of second contact pads under the bottom surface of the bridge substrate and coupled to the plurality of trenches. The first die and the second die may be coupled to the conductive layer through the plurality of first contact pads. The first die may be coupled to at least a respective one of the plurality of trenches through a corresponding one of the plurality of second contact pads. The second die may be coupled to at least an other respective one of the plurality of trenches through an other corresponding one of the plurality of second contact pads.

The present disclosure generally relates to a computing device. The computing device may include a printed circuit board and a semiconductor package coupled to the printed circuit board. The semiconductor package may include a package substrate, a bridge at least partially embedded in the package substrate, a first die and a second die on the package substrate. The bridge may include a bridge substrate, and a redistribution layer on a top surface of the bridge substrate. The bridge substrate may include a plurality of trenches extending vertically into the bridge substrate from a bottom surface of the bridge substrate, wherein each trench of the plurality of trenches may include a conductive filling. The bridge substrate may further include a conductive layer partially surrounding the plurality of trenches and separated from the plurality of trenches by a dielectric layer, a plurality of first contact pads under the bottom surface of the bridge substrate and coupled to the conductive layer, and a plurality of second contact pads under the bottom surface of the bridge substrate and coupled to the plurality of trenches. The first die and the second die may be coupled to the conductive layer through the plurality of first contact pads. The first die may be coupled to at least a respective one of the plurality of trenches through a corresponding one of the plurality of second contact pads. The second die may be coupled to at least an other respective one of the plurality of trenches through an other corresponding one of the plurality of second contact pads.

To more readily understand and put into practice the aspects of the present semiconductor package, particular aspects will now be described by way of examples and not limitations, and with reference to the figures. For the sake of brevity, duplicate descriptions of features and properties may be omitted.

It should be understood that the terms “on”, “under”, “top”, “bottom”, etc., when used in this description are used for convenience and to aid understanding of relative positions or directions, and not intended to limit the orientation of any device, or structure or any part of any device or structure.

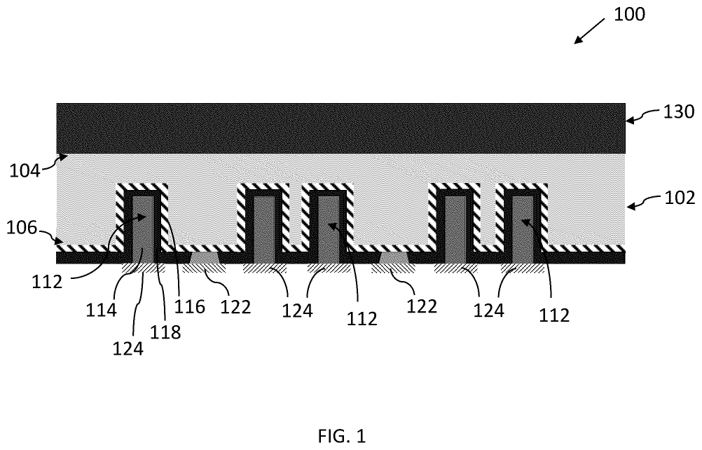

In an aspect shown in FIG. 1, a semiconductor device 100 of the present disclosure is shown in a cross-sectional view layout, including a bridge substrate 102, and a redistribution layer (RDL) 130 on a top surface 104 of the bridge substrate 102. The bridge substrate 102 may include a plurality of trenches 112 extending vertically into the bridge substrate 102 from a bottom surface 106 of the bridge substrate 102, wherein each trench 112 of the plurality of trenches 112 may include a conductive filling 114. The bridge substrate 102 may include a conductive layer 116 partially surrounding the plurality of trenches 112 and separated from the plurality of trenches 112 by a dielectric layer 118. The bridge substrate 102 may further include a plurality of first contact pads 122 under the bottom surface 106 of the bridge substrate 102 and coupled to the conductive layer 116, and a plurality of second contact pads 124 under the bottom surface 106 of the bridge substrate 102 and coupled to the conductive fillings 114 of the plurality of trenches 112.

According to various aspects of the present disclosure, the plurality of trenches 112 may be entirely filled with the conductive fillings 114, and may be referred to as the plurality of conductive trenches. The plurality of trenches 112 may be coupled to a power supply in an aspect, and may be referred to as power trenches accordingly. The plurality of trenches 112 may be coupled to ground in another aspect, and may be referred to as ground trenches accordingly. In an aspect, the conductive fillings 114 may include copper (Cu), titanium nitride (TiN), or tin-silver (SnAg) composites.

According to various aspects of the present disclosure, the plurality of trenches 112 may have a height substantially larger than a width, and may be referred to as deep trenches. In an aspect, the trenches 112 may have a high aspect ratio greater than 4:1. In another aspect, the trenches 112 may have a high aspect ratio greater than 10:1. In an example, the aspect ratio of the trenches 112 may be about 10:1.

In an aspect, the plurality of trenches 112 may be configured spaced apart from the top surface 104 of the bridge substrate 102. In other words, the plurality of trenches 112 may have one end exposed from the bottom surface 106 of the bridge substrate 102, while have another end spaced apart from the top surface 104 of the bridge substrate 102, as shown in FIG. 1. The end of the trenches 112 exposed from the bottom surface 106 of the bridge substrate 102 may be in physical contact with the second contact pads 124. According to an example, the heights of the plurality of trenches 112 may be about 20%-80% of a thickness of the bridge substrate 102. In an example, the thickness of the bridge substrate 102 may be in a range from about 50 μm to about 300 μm.

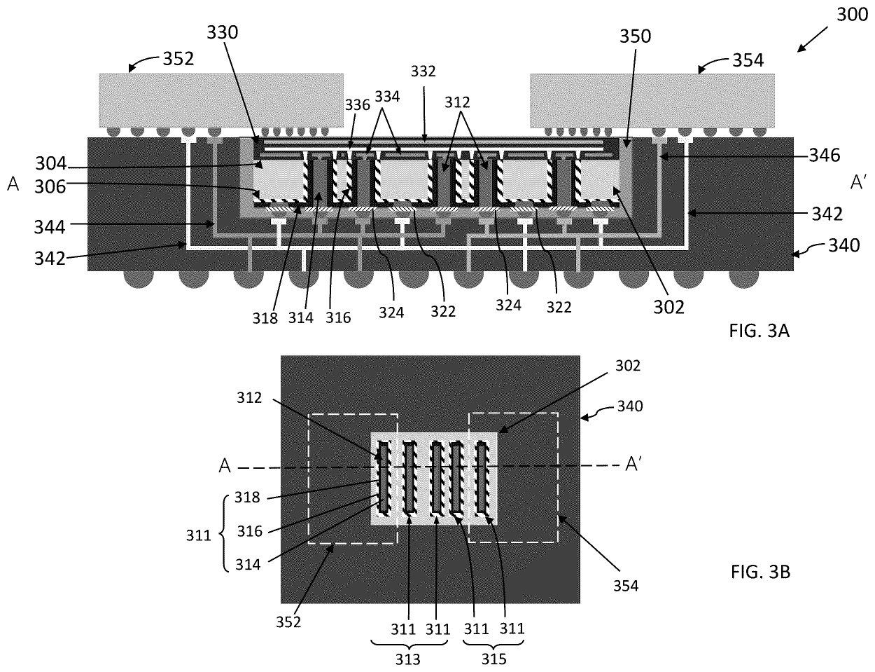

In another aspect, the plurality of trenches 112 may extend vertically through the bridge substrate 102, as shown in FIG. 3A below. In other words, the plurality of trenches 112 may have one end exposed from the bottom surface 106 of the bridge substrate 102, and have another end exposed from the top surface 104 of the bridge substrate 102.

The plurality of trenches 112 may be spaced apart from each other, wherein the intervals between adjacent trenches may be the same or may be different. It is understood that the dimensions, e.g., the height, the width, and/or the aspect ratio, of the trenches 112 may be the same or may be different from each other.

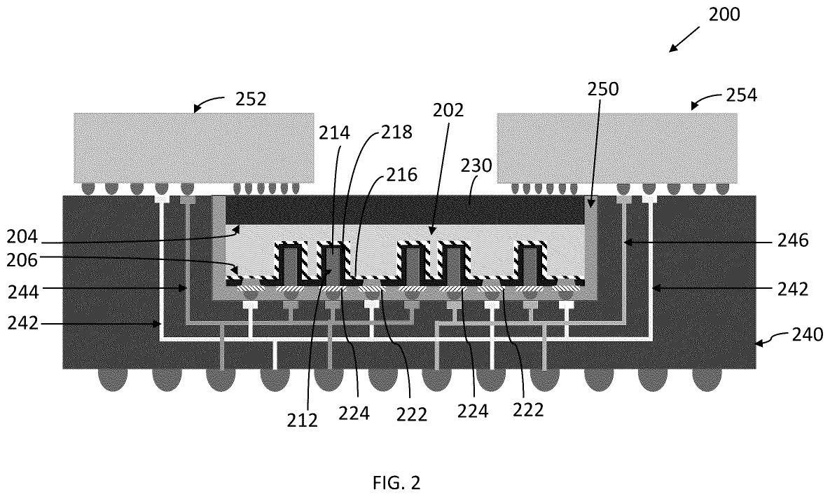

According to an aspect of the present disclosure, the conductive layer 116 may further extend along the bottom surface 106 of the bridge substrate 102 and may extend between the plurality of trenches 112. The dielectric layer 118 may further extend along the conductive layer 116 and may extend between the plurality of trenches 112. In an aspect, the conductive layer 116 and the dielectric layer 118 may each be a continuous layer extending along the periphery of the trenches 112 and between the trenches 112, as shown in in the examples of FIG. 1 and FIG. 2.

The dielectric layer 118 may include a high-k material having a relative permittivity of 20-15000. In an example, the high-k material may include calcium copper titanium oxide (CCTO) or barium titanate (BaTiO₃). In an aspect, the dielectric layer 118 may include hafnium dioxide (HfO₂).

The plurality of first contact pads 122 and the plurality of second contact pads 124 may lie in a same plane under the bottom surface 106 of the bridge substrate 102. In other words, the first contact pads 122 and the second contact pads 124 may be levelled under the bottom surface 106 of the bridge substrate 102. The plurality of first contact pads 122 are labelled differently from the plurality of second contact pads 124 in the drawings for convenience and to aid understanding of relative positions or couplings. It is understood that the plurality of first contact pads 122 may include the same conductive material as or may include different conductive materials from the plurality of second contact pads 124. It is also understood that the plurality of first contact pads 122 and the plurality of second contact pads 124 may be formed simultaneously or separately.

According to various aspects of the present disclosure, the conductive layer 116, the dielectric layer 118 and the conductive fillings 114 of the plurality of trenches 112 may form an array of capacitors, e.g., an array of deep trench capacitors (DTC), which may be used as decoupling capacitors. The conductive layer 116 may form a first terminal of the capacitor, and the conductive fillings 114 of the trenches 112 may form a second terminal of the capacitor. The deep trench capacitors have very high capacitance density, especially when they are coupled in parallel, and when combined with the bridge substrate may be used to form a dense structure for improved power delivery.

In an aspect, the conductive layer 116 may be coupled to a reference voltage, e.g., a ground (Vss) reference voltage. The plurality of trenches 112 may be coupled to a power (Vcc) supply voltage. Accordingly, the inner ground layer 116 may be a continuous plane or layer across all the vertical trenches 112, and the vertical deep trench conductors 112 may be connected to power domain to form the capacitance with the ground layer 116. In another example, the plurality of trenches 112 may include a first group and a second group. The first group of trenches may be coupled to a first power supply voltage, and the second group of trenches may be coupled to a second power supply voltage different from the first power supply voltage. Accordingly, multiple power domain decoupling capacitors may be formed by connecting the vertical deep trench conductors 112 to different power sources.

In another example, the conductive layer 116 may be coupled to the power (Vcc) supply voltage, and the trenches 112 may be coupled to the ground (Vss) reference voltage. In a further example, the conductive layer 116 may be partitioned or interrupted between the trenches 112 (not shown in FIG. 1), such that the segments of the conductive layer 116 associated with the first group of trenches may be coupled to the first power supply voltage and the segments of the conductive layer 116 associated with the second group of trenches may be coupled to the second power supply voltage to form multiple power domain decoupling capacitors.

According to a further aspect of the present disclosure, the conductive layer 116 and the plurality of trenches 112 may be coupled to the redistribution layer 130. In an aspect, the conductive layer 116 may surround only the sidewalls of the trenches 112 and may be absent over the top surface of the trenches 112 to expose the conductive filling of the trenches for coupling with the redistribution layer 130 (e.g., for coupling with a power layer in the redistribution layer) from the top surface of the bridge substrate, as shown in the example of FIG. 3A below. The conductive layer 116 may also be coupled with the redistribution layer 130 (e.g., with a ground layer in the redistribution layer) from the top surface of the bridge substrate.

The bridge substrate 102 may include a silicon substrate, a glass-based substrate, a ceramic substrate, or an organic substrate. In an aspect, the organic bridge substrate may include a thermoset epoxy polymer, silicone or composites molding compound. The redistribution layer (RDL) 130 may include one or more metal layers isolated by one or more dielectric layers, wherein metal interconnection or metal traces may be formed in the metal layers to route electrical signals between various dies in a semiconductor package. In an aspect, the RDL 130 may include a signal layer for signal transmission, and one or more reference voltage layers, e.g., a ground reference voltage (Vss) plane and/or a power supply voltage (Vcc) plane. The device 100 including the bridge substrate 102 and the redistribution layer 130 may form a bridge, which may be referred to as an embedded multi-die interconnect bridge (EMIB) and may be embedded in an integrated circuit package to connect one chip to another. According to various aspects, deep trench capacitors may be implemented at the backside of the bridge to leverage the available EMIR substrate area.

According to various aspect of the present disclosure, the device 100 may further include a package substrate, wherein the bridge substrate 102 and the redistribution layer 130 may be at least partially embedded in the package substrate as shown in FIG. 2 and FIG. 3A below. The package substrate may include contact pads, electrical interconnects and routings, and other features, for signal routing and electrical connection to various devices and components.

The conductive layer 116 and the plurality of trenches 112 may be coupled to the package substrate through the plurality of first contact pads 122 and the plurality of second contact pads 124, respectively.

In an aspect, the device 100 may further include a first die and a second die on the package substrate, wherein the first die and the second die may be coupled through the redistribution layer 130 as shown in FIG. 2 and FIG. 3A below.

The conductive layer 116 may be coupled to the first die and the second die through the plurality of first contact pads 122, and each of the plurality of trenches 112 may be coupled to at least one of the first die or the second die through a respective one of the plurality of second contact pads 124. Accordingly, the decoupling capacitors in the bridge substrate 102 may be coupled to the first die and the second die through the first contact pads 122 and the second contact pads 124 from the bottom surface 106 of the bridge substrate 102.

In a further aspect, the conductive layer 116 and each of the plurality of trenches 112 may be coupled to at least one of the first die or the second die through the redistribution layer 130. Accordingly, the decoupling capacitors in the bridge substrate 102 may be further coupled to the first die and the second die through the redistribution layer 130 from the top surface 104 of the bridge substrate 102. In an aspect, the conductive layer 116 may include a copper (Cu) layer or a titanium nitride (TiN) layer. In an aspect, an insulation layer (not shown) e.g., a silicon dioxide (SiO₂) layer may be formed in between the bridge substrate 102 and the conductive layer 116 for improved reliability.

FIG. 2 shows a cross-sectional view of a semiconductor device 200 according to another aspect of the present disclosure.

Many of the aspects of the semiconductor device 200 are the same or similar to those of the semiconductor device 100. For the sake of brevity, duplicate descriptions of features and properties are omitted. Accordingly, it will be understood that the descriptions of any feature and/or property relating to FIG. 2 that are the same or similar to a feature and/or property in FIG. 1 will have those descriptions be applicable hereinbelow as well.

In the aspect shown in FIG. 2, a semiconductor device 200 of the present disclosure is shown in a cross-sectional view layout, including a bridge substrate 202, and a redistribution layer (RDL) 230 on a top surface 204 of the bridge substrate 202. The bridge substrate 202 may include a plurality of trenches 212 extending vertically into the bridge substrate 202 from a bottom surface 206 of the bridge substrate 202, wherein each trench 212 may include a conductive filling 214. The bridge substrate 202 may include a conductive layer 216 partially surrounding the plurality of trenches 212 and separated from the plurality of trenches 212 by a dielectric layer 218. The bridge substrate 202 may further include a plurality of first contact pads 222 under the bottom surface 206 of the bridge substrate 202 and coupled to the conductive layer 216, and a plurality of second contact pads 224 under the bottom surface 206 of the bridge substrate 202 and coupled to the conductive fillings 214 of the plurality of trenches 212.

The plurality of trenches 212 may be entirely filled with the conductive fillings 214, and may be referred to as the plurality of conductive trenches. The plurality of trenches 212 may be coupled to a power supply in an aspect, and may be referred to as power trenches accordingly. The plurality of trenches 212 may be coupled to ground in another aspect, and may be referred to as ground trenches accordingly.

According to various aspects of the present disclosure, the plurality of trenches 212 may have a height substantially larger than a width, and may be referred to as deep trenches. In an aspect, the trenches 212 may have a high aspect ratio greater than 4:1. In another aspect, the trenches 212 may have a high aspect ratio greater than 10:1. In an example, the aspect ratio of the trenches 212 may be about 10:1.

In an aspect, the plurality of trenches 212 may be configured spaced apart from the top surface 204 of the bridge substrate 202. As shown in FIG. 2, the plurality of trenches 212 may have one end exposed from the bottom surface 206 of the bridge substrate 202, while have another end spaced apart from the top surface 204 of the bridge substrate 202. The end of the trenches 212 exposed from the bottom surface 206 of the bridge substrate 202 may be in physical contact with the second contact pads 224. According to an example, the heights of the plurality of trenches 212 may be about 20%-80% of a thickness of the bridge substrate 202.

The plurality of trenches 212 may be spaced apart from each other, wherein the intervals between adjacent trenches may be the same or may be different. It is understood that the dimensions, e.g., the height, the width, and/or the aspect ratio, of the trenches 212 may be the same or may be different from each other.

Similar to FIG. 1, the conductive layer 216 may further extend along the bottom surface 206 of the bridge substrate 202 and may extend between the plurality of trenches 212. The dielectric layer 218 may further extend along the conductive layer 216 and may extend between the plurality of trenches 212. As shown in FIG. 2, the conductive layer 216 and the dielectric layer 218 may each be a continuous layer extending along the periphery of the trenches 212 and between the trenches 212. The dielectric layer 218 may include a high-k material having a relative permittivity of 20-15000. In an example, the high-k material may include calcium copper titanium oxide (CCTO) or barium titanate (BaTiO₃). In an aspect, the dielectric layer 218 may include hafnium dioxide (HfO₂).

The plurality of first contact pads 222 and the plurality of second contact pads 224 may lie in a same plane under the bottom surface 206 of the bridge substrate 202. In other words, the first contact pads 222 and the second contact pads 224 may be levelled under the bottom surface 206 of the bridge substrate 202.

The conductive layer 216, the dielectric layer 218 and the conductive fillings 214 of the plurality of trenches 212 may form an array of capacitors, e.g., an array of deep trench capacitors, which may serve as decoupling capacitors. The conductive layer 216 may form a first terminal of the capacitors, and the conductive fillings 214 of the trenches 212 may form a second terminal of the capacitors.

In an aspect, the conductive layer 216 may be coupled to a reference voltage, e.g., a ground (Vss) reference voltage. The plurality of trenches 212 may be coupled to a power (Vcc) supply voltage. Accordingly, the inner ground layer 216 may be a continuous plane across all the vertical trenches 212, and the vertical deep trench conductors 212 may be connected to power domain to form the capacitance with the ground layer 216. In another example, the plurality of trenches 212 may include a first group and a second group. The first group of trenches may be coupled to a first power supply voltage, and the second group of trenches may be coupled to a second power supply voltage different from the first power supply voltage. Accordingly, multiple power domain decoupling capacitors may be formed by connecting the vertical deep trench conductors 212 to different power sources.

In another example, the conductive layer 216 may be coupled to the power (Vcc) supply voltage, and the trenches 212 may be coupled to the ground (Vss) reference voltage. In a further example, the conductive layer 216 may be partitioned or interrupted between the trenches 212 (not shown in FIG. 2), such that the segments of the conductive layer 216 associated with the first group of trenches may be coupled to the first power supply voltage and the segments of the conductive layer 216 associated with the second group of trenches may be coupled to the second power supply voltage to form multiple power domain decoupling capacitors.

Similar to FIG. 1, the bridge substrate 202 may include a silicon substrate, a glass-based substrate, a ceramic substrate, or an organic substrate. The redistribution layer (RDL) 230 may include one or more metal layers isolated by one or more dielectric layers. In an aspect, the RDL 230 may include a signal layer for signal routing between various dies in a semiconductor package, and one or more reference voltage layers, e.g., a ground reference voltage (Vss) plane and/or a power supply voltage (Vcc) plane. The bridge substrate 202 and the redistribution layer 230 may form a bridge, which may be referred to as an embedded multi-die interconnect bridge (EMIB) and may be embedded in the device 200 (also referred to as a semiconductor package or an integrated circuit package) to connect one chip to another. According to various aspects, deep trench capacitors may be implemented at the backside of the bridge to leverage the available EMIR substrate area.

According to various aspect of FIG. 2, the device 200 may further include a package substrate 240, wherein the bridge including the bridge substrate 202 and the redistribution layer 230 may be at least partially embedded in the package substrate 240. The package substrate 240 may include contact pads, electrical interconnects and routings, and other features, for signal routing and electrical connection to various devices and components. An underfill layer 250 may be provided to fill a gap between the package substrate 240 and the bridge, and to cover and protect the solder bumps.

The bridge may be coupled to the package substrate 240 at the bottom surface through the first and second contact pads 222, 224. As shown in FIG. 2, the bridge substrate 202 may be electrically coupled to the package substrate 240 through the first and second contact pads 222, 224, the solder bumps and the contact pads of the package substrate 240. The conductive layer 216 and the plurality of trenches 212 may be coupled to the package substrate 240 through the first contact pads 222 and the second contact pads 224, respectively.

The semiconductor package 200 may further include a first die 252 and a second die 254 on the package substrate 240. The first die 252 and the second die 254 may be coupled through the redistribution layer 230, which may be configured for signal routing and power delivery between the first die 252 and the second die 254. In an aspect as shown in FIG. 2, the first die 252 and the second die 254 may be spaced apart from each other, and may each overlie both the package substrate 240 and the bridge for electrical coupling to the package substrate 240 and the bridge.

The bridge at least partially embedded within the package substrate 240 may facilitate electrical interconnects between the first die 252 and the second die 254. In an aspect, the first die 252 may be a first silicon device, e.g., a central processing unit (CPU) or a graphic processing unit (GPU). The second die 254 may be a second silicon device, e.g., a platform controller hub (PCH), a DRAM memory, an I/O tile or a field programmable gate array (FPGA) device.

In an aspect, the first die 252 and the second die 254 may be coupled to the plurality of deep trench capacitors through the first and second contact pads 222, 224 and the package substrate 240 to facilitate improved power delivery, e.g., supply of charges from the deep trench capacitor storage.

The conductive layer 216 may be coupled to the first die 252 and the second die 254 through the first contact pads 222, and each of the plurality of trenches 212 may be coupled to at least one of the first die 252 or the second die 254 through a respective one of the plurality of second contact pads 224. Accordingly, the deep trench capacitors in the bridge substrate 202 may be coupled to the first die 252 and the second die 254 through the first contact pads 222 and the second contact pad 224 from the bottom surface 206 of the bridge substrate 202.

In an aspect, the conductive layer 216, the first die 252 and the second die 254 may be coupled to a reference voltage, e.g., the ground (Vss) reference voltage, as represented by the connections 242 in FIG. 2. The plurality of trenches 212 may be coupled to one or more power (Vcc) supply voltages. In an example as shown in FIG. 2, the plurality of trenches 212 may include a first group and a second group. The first group of trenches and the first die 252 may be coupled to a first power supply voltage provided by a first power supply, e.g., a 1.0V supply, as represented by the connections 244 in FIG. 2. The second group of trenches and the second die 254 may be coupled to a second power supply voltage provided by a second power supply, e.g., a 1.8V supply, as represented by the connections 246 in FIG. 2. The second power voltage may be different from the first power supply voltage.

Various aspects of FIG. 2 provide a multi-chip electronic package 200 with a deep trench capacitor (DTC) bridge for improved electrical performance and device miniaturization. The semiconductor package 200 may be coupled to a printed circuit board (not shown), e.g., a motherboard, through solder balls and associated contact pads.

FIG. 3A shows a cross-sectional view of a semiconductor device 300 along line A-A′ of FIG. 3B according to a further aspect of the present disclosure, and FIG. 3B shows a top view layout of the semiconductor device 300 according to the aspect as shown in FIG. 3A.

Many of the aspects of the semiconductor device 300 are the same or similar to those of the semiconductor devices 100, 200. For the sake of brevity, duplicate descriptions of features and properties are omitted. Accordingly, it will be understood that the descriptions of any feature and/or property relating to FIG. 3A and FIG. 3B that are the same or similar to a feature and/or property in FIG. 1 and FIG. 2 will have those descriptions be applicable hereinbelow as well.

In the aspect shown in FIG. 3A, a semiconductor device 300 of the present disclosure is shown in a cross-sectional view layout, including a bridge substrate 302, and a redistribution layer (RDL) 330 on a top surface 304 of the bridge substrate 302. The bridge substrate 302 may include a plurality of trenches 312 extending vertically into the bridge substrate 302 from a bottom surface 306 of the bridge substrate 302, wherein each trench 312 may include a conductive filling 314. The bridge substrate 302 may include a conductive layer 316 partially surrounding the plurality of trenches 312 and separated from the plurality of trenches 312 by a dielectric layer 318. The bridge substrate 302 may further include a plurality of first contact pads 322 under the bottom surface 306 of the bridge substrate 302 and coupled to the conductive layer 316, and a plurality of second contact pads 324 under the bottom surface 306 of the bridge substrate 302 and coupled to the conductive fillings 314 of the plurality of trenches 312.

Similar to FIG. 1 and FIG. 2 above, the plurality of trenches 312 may be entirely filled with the conductive fillings 314, and may be referred to as the plurality of conductive trenches. The plurality of trenches 312 may be power trenches coupled to a power supply in an aspect, or may be ground trenches coupled to a ground voltage in another aspect.

The plurality of trenches 312 may be deep trenches having a height substantially larger than a width. In an example, an aspect ratio of the trench 312 may be about 10:1. The plurality of trenches 312 may be spaced apart from each other, wherein the intervals between adjacent trenches may be the same or may be different. It is understood that the dimensions, e.g., the height, the width, and/or the aspect ratio, of the trenches 312 may be the same or may be different from each other.

In an aspect as shown in FIG. 3A, the plurality of trenches 312 may extend vertically through the bridge substrate 302. In other words, the plurality of trenches 312 may have one end exposed from the bottom surface 306 of the bridge substrate 302, and have another end exposed from the top surface 304 of the bridge substrate 302. The end of the trenches 312 exposed from the bottom surface 306 of the bridge substrate 302 may be in physical contact with the second contact pads 324.

Similar to FIG. 1 and FIG. 2, the conductive layer 316 may further extend along the bottom surface 306 of the bridge substrate 302 and may extend between the plurality of trenches 312. The dielectric layer 318 may further extend along the conductive layer 316 and may extend between the plurality of trenches 312.

According to an aspect of FIG. 3A, the conductive layer 316 may surround only the sidewalls of the trenches 312 and may be absent over the top surface of the trenches 312, to expose the conductive filling 314 of the trenches 312 for coupling with the redistribution layer 330 (e.g., for coupling with a power (Vcc) layer 334 in the redistribution layer 330) from the top surface 304 of the bridge substrate 302. Accordingly, the plurality of trenches 312 may be coupled to the redistribution layer 330. In a further aspect, the conductive layer 316 may also be coupled to the redistribution layer 330 (e.g., to a ground (Vss) layer 336 in the redistribution layer 330) from the top surface 304 of the bridge substrate 302.

The conductive layer 316, the dielectric layer 318 and the conductive fillings 314 of the plurality of trenches 312 may form an array of capacitors 311 as shown in FIG. 3B, e.g., an array of deep trench capacitors, which may serve as decoupling capacitors. The conductive layer 316 may form a first terminal of the capacitors 311, and the conductive fillings 314 of the trenches 312 may form a second terminal of the capacitors 311.

Similar to the disclosure of FIG. 1 and FIG. 2 above, the conductive layer 316 may be coupled to a reference voltage, e.g., a ground (Vss) reference voltage, and the plurality of trenches 312 may be coupled to one or more power (Vcc) supply voltages. In another example, the conductive layer 316 may be coupled to one or more power (Vcc) supply voltages, and the trenches 312 may be coupled to the ground (Vss) reference voltage, as described above.

In an aspect, the redistribution layer (RDL) 330 may include one or more metal layers isolated by one or more dielectric layers. As illustrated in FIG. 3, the RDL 330 may include a signal layer 332 to facilitate signal transmission between various silicon devices in the semiconductor package 300. The RDL 330 may include a power (Vcc) layer 334 to facilitate power delivery between various silicon devices. The RDL 330 may further include a ground (Vss) layer 336 to facilitate current return path and/or to facilitate a shielding layer for the signal layer and/or the power layer. The bridge substrate 302 and the redistribution layer 330 may form a bridge, which may be referred to as an embedded multi-die interconnect bridge (EMIR), wherein deep trench capacitors 311 may be implemented at the backside of the bridge to leverage the available EMIR substrate area.

According to various aspect of FIGS. 3A and 3B, the semiconductor package 300 may further include a package substrate 340, wherein the bridge including the bridge substrate 302 and the redistribution layer 330 may be at least partially embedded in the package substrate 340. The package substrate 340 may include contact pads, electrical interconnects and routings, and other features, for signal routing and electrical connection to various devices and components. An underfill layer 350 may be provided to fill a gap between the package substrate 340 and the bridge, and to cover and protect the solder bumps.

The bridge may be coupled to the package substrate 340 at the bottom surface through the first and second contact pads 322, 324. As shown in FIG. 3A, the bridge substrate 302 may be electrically coupled to the package substrate 340 through the first and second contact pads 322, 324, the solder bumps and the contact pads of the package substrate 340. The conductive layer 316 and the plurality of trenches 312 may be coupled to the package substrate 340 through the first contact pads 322 and the second contact pads 324, respectively.

Similar to FIG. 2, the semiconductor package 300 may further include a first die 352 and a second die 354 on the package substrate 340. The first die 352 and the second die 354 may be coupled through the redistribution layer 330, which may be configured for signal routing and power delivery between the first die 352 and the second die 354. In an aspect, the first die 352 and the second die 354 may be spaced apart from each other, and may each overlie both the package substrate 340 and the bridge for electrical coupling to the package substrate 340 and the bridge.

The bridge at least partially embedded within the package substrate 340 may facilitate electrical interconnects between the first die 352 and the second die 354. In an aspect, the first die 352 may be a central processing unit (CPU) or a graphic processing unit (GPU). The second die 354 may be a platform controller hub (PCH), a DRAM memory, an I/O tile or a field programmable gate array (FPGA) device.

In an aspect, the first die 352 and the second die 354 may be coupled to the plurality of deep trench capacitors 311 through the first and second contact pads 322, 324 and the package substrate 340 to facilitate improved power delivery, e.g., supply of charges from the deep trench capacitor storage.

The conductive layer 316 may be coupled to the first die 352 and the second die 354 through the plurality of first contact pads 322, and each of the plurality of trenches 312 may be coupled to at least one of the first die 352 or the second die 354 through a respective one of the plurality of second contact pads 324. In an example as shown in FIG. 3A and FIG. 3B, a first group 313 of capacitors 311 including the first group of trenches may be coupled to the first die 352 through the respective second contact pads 324. In an example, the first group 313 of capacitors 311 may be coupled in parallel. A second group 315 of capacitors 311 including the second group of trenches may be coupled to the second die 354 through the respective second contact pads 324. In an example, the second group 315 of capacitors 311 may be coupled in parallel. Accordingly, the deep trench capacitors 311 in the bridge substrate 302 may be coupled to the first die 352 and the second die 354 through the first contact pads 322 and the second contact pads 324 from the bottom surface 306 of the bridge substrate 302.

In an aspect, the conductive layer 316, the first die 352 and the second die 354 may be coupled to a reference voltage, e.g., the ground (Vss) reference voltage, as represented by the connections 342 in FIG. 3A. The plurality of trenches 312 may be coupled to one or more power (Vcc) supply voltages. In an example as shown in FIG. 3A, the plurality of trenches 312 may include a first group 313 and a second group 315. The first group 313 of trenches 312 and the first die 352 may be coupled to a first power supply voltage provided by a first power supply, e.g., a 1.0V supply, as represented by the connections 344 in FIG. 3A. The second group 315 of trenches 312 and the second die 354 may be coupled to a second power supply voltage provided by a second power supply, e.g., a 1.8V supply, as represented by the connections 346 in FIG. 3A.

In a further aspect of FIG. 3A, the conductive layer 316 and each of the plurality of trenches 312 may be coupled to at least one of the first die 352 or the second die 354 through the redistribution layer 330. In an aspect, the trenches 312 may be coupled to the power layer 334 within the RDL 330 to facilitate power delivery between the first and second dies 352, 354. The conductive layer 316 may be coupled to the ground (Vss) layer 336 within the RDL 330. Accordingly, the decoupling capacitors 311 in the bridge substrate 302 may be further coupled to the first die 352 and the second die 354 through the redistribution layer 330 from the top surface 304 of the bridge substrate 302.

According to various aspects described above, a multi-chip electronic package 300 with a deep trench capacitor (DTC) bridge may be provided for improved electrical performance and device miniaturization. The semiconductor package 300 may be coupled to a printed circuit board (not shown), e.g., a motherboard, through solder balls and associated contact pads.

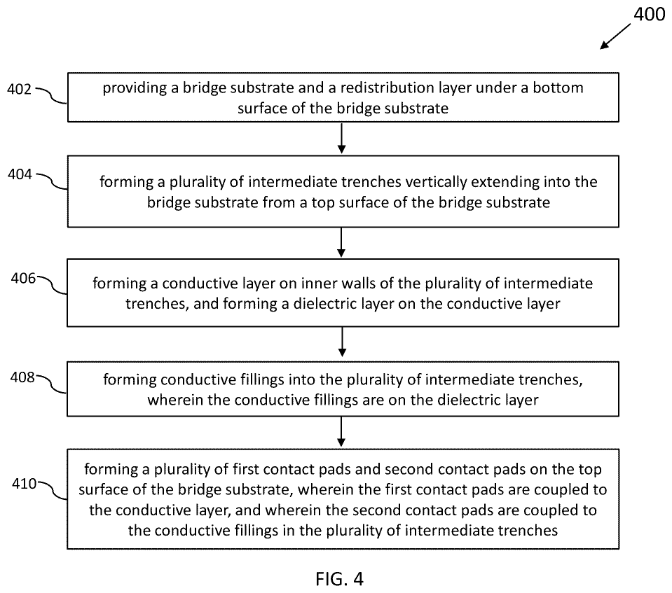

FIG. 4 shows a flowchart 400 illustrating a method of forming a device, such as the device 100, 200, 300 of FIGS. 1, 2 and 3A-3B, according to an aspect of the present disclosure. Various aspects described with reference to FIGS. 1, 2 and 3A-3B may be similarly applied for the method of FIG. 4.

At 402, a bridge substrate and a redistribution layer under a bottom surface of the bridge substrate may be provided.

At 404, a plurality of intermediate trenches vertically extending into the bridge substrate from a top surface of the bridge substrate may be formed.

At 406, a conductive layer may be formed on inner walls of the plurality of intermediate trenches, and a dielectric layer may be formed on the conductive layer.

At 408, conductive fillings may be formed into the plurality of intermediate trenches, wherein the conductive fillings may be on the dielectric layer.

At 410, a plurality of first contact pads and a plurality of second contact pads may be formed on the top surface of the bridge substrate, wherein the plurality of first contact pads may be coupled to the conductive layer, and wherein the plurality of second contact pads may be coupled to the conductive fillings in the plurality of intermediate trenches.

According to an aspect of the present disclosure, the method may further include at least partially embedding the bridge substrate and the redistribution layer in a package substrate, wherein the conductive layer and the conductive fillings are coupled to the package substrate through the plurality of first contact pads and the plurality of second contact pads, respectively.

In an aspect, the method may further include arranging a first die and a second die on the package substrate, wherein the first die and the second die are coupled to the conductive layer through the plurality of first contact pads and each are coupled to a respective one of the conductive fillings through a corresponding one of the plurality of second contact pads.

It will be understood that the operations described above relating to FIG. 4 are not limited to this particular order. Any suitable, modified order of operations may be used.

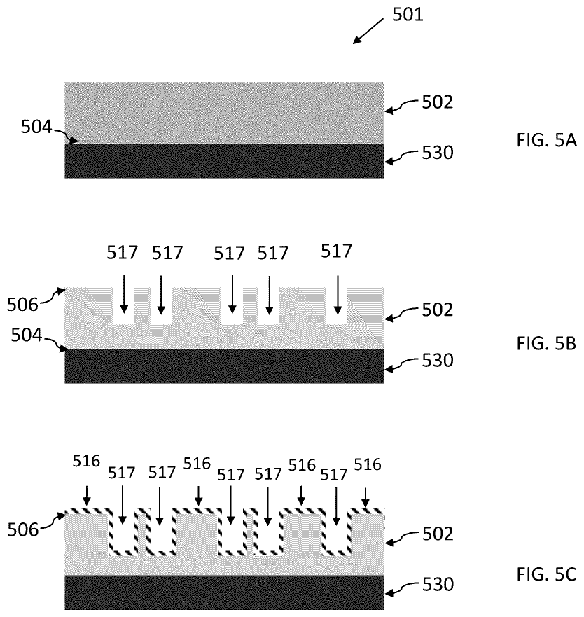

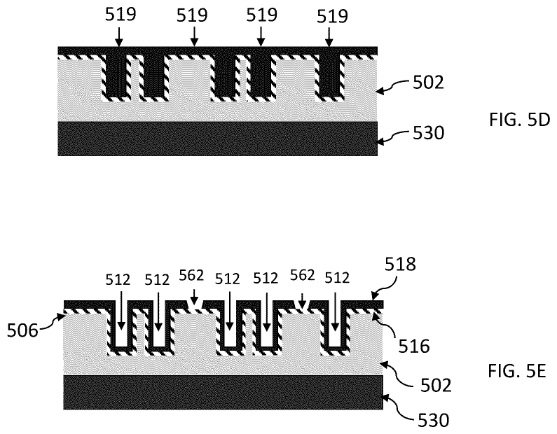

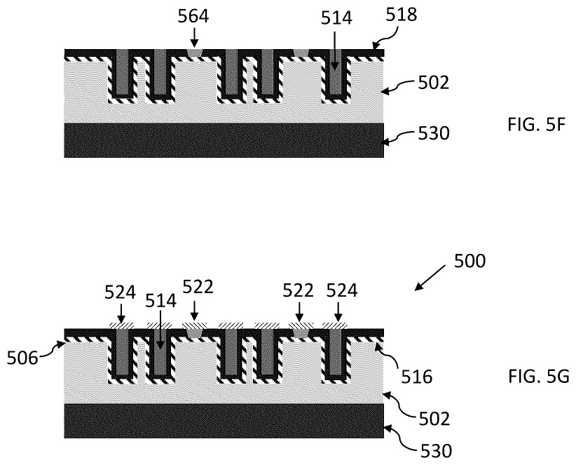

FIGS. 5A through 5G show cross-sectional views directed to an exemplary process flow for a method of making a semiconductor device (e.g., the device 100, 200, 300) according to an aspect of the present disclosure. Various aspects described with reference to FIGS. 1, 2, and 3A-3B may be similarly applied for the process flow of FIG. 5A-5G.

In FIG. 5A, a bridge 501 including a bridge substrate 502 and a redistribution layer 530 on a first surface 504 of the bridge substrate 502 may be provided. The bridge 501 may be an EMIB, and may be flipped with the bridge substrate 502 facing up. Accordingly, the redistribution layer 530 may appear under the bridge substrate 502 in FIG. 5A.

In FIG. 5B, a plurality of intermediate trenches 517 may be formed to vertically extend into the bridge substrate 502 from a second surface 506 of the bridge substrate 502, e.g., through a mechanical or laser drilling process. The second surface 506 may be opposing the first surface 504.

In FIG. 5C, a conductive layer 516 may be formed on inner walls of the plurality of intermediate trenches 517, e.g., through an electroless or electrolytic plating process. The conductive layer 516 may extend along the second surface 506 of the bridge substrate 502 and extend between the plurality of intermediate trenches 517. In an aspect, an insulation layer (not shown), e.g., a silicon dioxide (SiO₂) layer may be formed between the conductive layer 516 and the bridge substrate 502. For example, the insulation layer may be formed on the inner walls of the plurality of intermediate trenches 517 prior to the deposition of the conductive layer 516.

In FIG. 5D, dielectric materials 519 may be formed on the conductive layer 516 and may be filled into the plurality of intermediate trenches 517, e.g., through polymer filling, spin coating, printing or spraying process.

In FIG. 5E, a dielectric layer 518 may be formed on the conductive layer 516, e.g., through an etching or a laser drilling process, wherein portions of the dielectric materials 519 within the plurality of intermediate trenches 517 may be removed to form a plurality of trenches 512 and portions of the dielectric materials 519 on the second surface 506 of the bridge substrate 502 may be removed to form a plurality of recesses 562.

In FIG. 5F, conductive fillings may be formed on the dielectric layer 518, e.g., through an electroplating or printing process. Conductive materials may be filled into the plurality of trenches 512 to form the conductive fillings 514 of the trenches 512, and may be filled into the recesses 562 to form conductive vias 564.

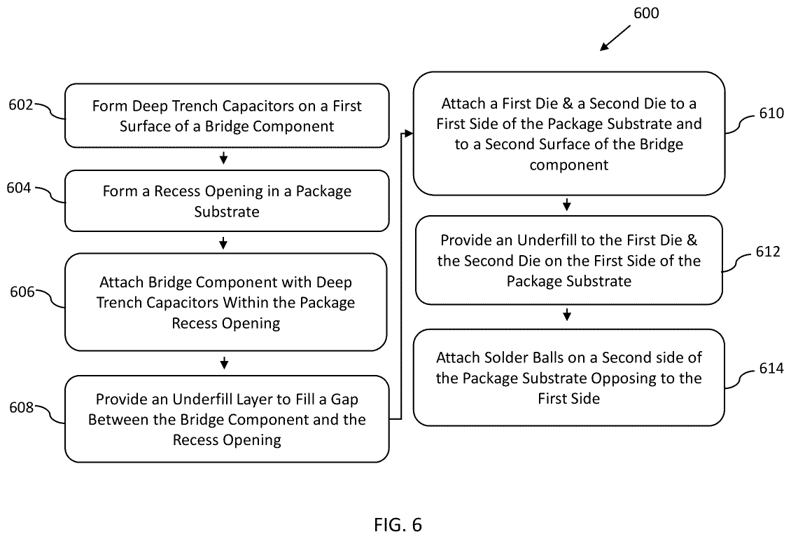

In FIG. 5G, a plurality of first contact pads 522 and second contact pads 524 may be formed over the second surface 506 of the bridge substrate 502, e.g., through an electrolytic plating or etching process. The first contact pads 522 may be formed on the vias 564, and may be coupled to the conductive layer 516 through the vias 564. The second contact pads 524 may be formed on the conductive fillings 514 of the trenches 512, and may be coupled to the conductive fillings 514 in the plurality of trenches 512. As shown in FIG. 5G, the first contact pads 522 may be in physical contact with the vias 564, and the second contact pads 524 may be in physical contact with the conductive fillings 514 of the trenches 512. The structure 500 of FIG. 5G may be similar to the device 100 of FIG. 1 above, and accordingly the device 100 may be manufactured according to the processes of FIGS. 5A-5G. The structure 500 of FIG. 5G may be referred to as the EMIB 500, which may be flipped over and embedded into a package substrate to form the device 200, 300 of FIGS. 2 and 3A above, as illustrated in FIG. 6 below.

FIGS. 5A-5G above illustrate an exemplary process flow to manufacture a silicon bridge with deep trench capacitors for multi-chip package applications. The operation order described above may be interchangeable to achieve optimum assembly yield and/or throughput time.

FIG. 6 shows a flowchart 600 illustrating a method of forming a device, such as the device 100, 200, 300 of FIGS. 1, 2 and 3A-3B, according to an aspect of the present disclosure. Various aspects described with reference to FIGS. 1, 2 and 3A-3B may be similarly applied for the method of FIG. 6.

At 602, deep trench capacitors may be formed on a first surface of a bridge component, e.g. through drilling, lamination, etching and/or electroplating processes. The fabrication of deep trench capacitors may be performed according to the exemplary process flow of FIGS. 5A-5G above, wherein the bridge component with deep trench capacitor may be similar to the EMIB 500 illustrated in FIG. 5G above.

At 604, a recess opening is formed in a package substrate, e.g., through a drilling or etching process.

At 606, the bridge component with deep trench capacitors may be attached or embedded within the recess opening of the package substrate, e.g., through a surface mounting or thermal compression bonding process.

At 608, an underfill layer may be provided to fill a gap between the bridge component and the recess opening, e.g., through a capillary dispense process.

At 610, a first die and a second die may be attached to a first side of the package substrate and to a second surface of the bridge component, e.g., through a surface mounting or thermal compression bonding process. The second surface of the bridge component may be opposing to the first surface.

At 612, an underfill may be provided to the first die and the second die on the first side of the package substrate, to fill a gap between the dies and the package substrate, e.g., through a capillary dispense process.

At 614, solder balls may be attached or formed on a second side of the package substrate opposing to the first side, e.g., through a surface mounting or thermal compression bonding process. The structure formed at 614 may be similar to the the device 200, 300 of FIGS. 2 and 3A above, and accordingly the device 200, 300 may be manufactured according to the processes of FIG. 6. The structure formed at 614 may be mounted onto a printed circuit board through the solder balls. Accordingly, FIG. 6 depicts a simplified process flow to assemble a multi-chip package with a deep-trench-capacitor bridge component according to various aspects of the present disclosure.

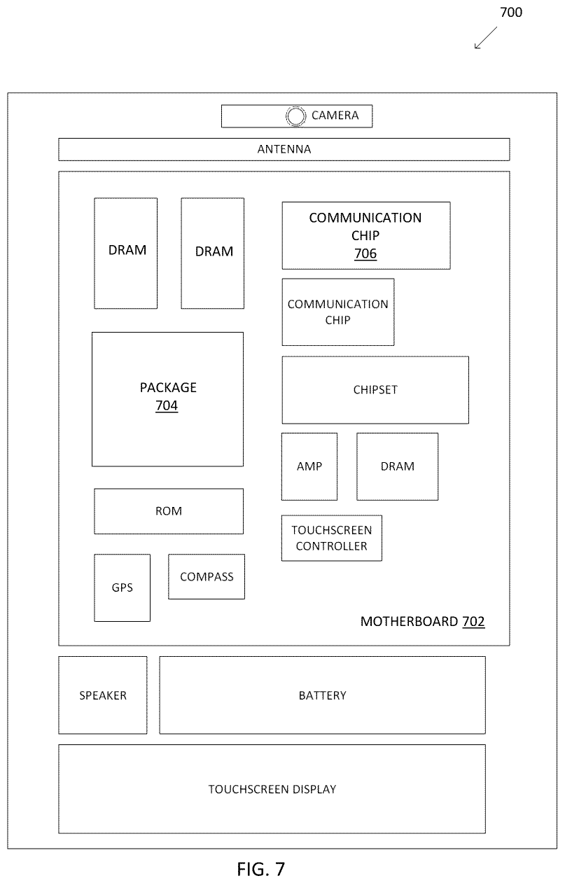

Aspects of the present disclosure may be implemented into a system using any suitable hardware and/or software. FIG. 7 schematically illustrates a computing device 700 that may include a semiconductor package 100, 200, 300, 500 as described herein, in accordance with some aspects. The computing device 700 may house a board such as a motherboard 702. The motherboard 702 may include several components, including but not limited to a semiconductor package 704, according to the present disclosure, and at least one communication chip 706. The semiconductor package 704, which may include a bridge with deep trench capacitors according to the present disclosure, may be physically and electrically coupled to the motherboard 702. In some implementations, the at least one communication chip 706 may also be physically and electrically coupled to the motherboard 702.

Depending on its applications, computing device 700 may include other components that may or may not be physically and electrically coupled to the motherboard 702. These other components may include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the semiconductor package 704 of the computing device 700 may be assembled with a plurality of passive devices, as described herein.

The communication chip 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 706 may implement any of several wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 706 may also operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 706 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 706 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 706 may operate in accordance with other wireless protocols in other aspects.

The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

In various implementations, the computing device 700 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 700 may be a mobile computing device. In further implementations, the computing device 700 may be any other electronic device that processes data.

### Examples

Example 1 may include a device, including a bridge substrate and a redistribution layer on a top surface of the bridge substrate. The bridge substrate may include a plurality of trenches extending vertically into the bridge substrate from a bottom surface of the bridge substrate, wherein each trench of the plurality of trenches may include a conductive filling; a conductive layer partially surrounding the plurality of trenches and separated from the plurality of trenches by a dielectric layer; a plurality of first contact pads under the bottom surface of the bridge substrate and coupled to the conductive layer; and a plurality of second contact pads under the bottom surface of the bridge substrate and coupled to the conductive fillings of the plurality of trenches.

Example 2 may include the subject matter of Example 1, wherein the plurality of trenches may be configured spaced apart from the top surface of the bridge substrate.

Example 3 may include the subject matter of Example 1, wherein the plurality of trenches may extend vertically through the bridge substrate.

Example 4 may include the subject matter of any one of Example 1 to 3, wherein the conductive layer may further extend along the bottom surface of the bridge substrate and extend between the plurality of trenches, and wherein the dielectric layer may further extend along the conductive layer and extend between the plurality of trenches.

Example 5 may include the subject matter of any one of Example 1 to 4, wherein the dielectric layer may include a high-k material having a relative permittivity of 20-15000.

Example 6 may include the subject matter of any one of Example 1 to 5, wherein the plurality of first contact pads and the plurality of second contact pads may lie in a same plane under the bottom surface of the bridge substrate.

Example 7 may include the subject matter of any one of Example 1 to 6, wherein the conductive layer, the dielectric layer and the conductive fillings of the plurality of trenches may form an array of capacitors.

Example 8 may include the subject matter of any one of Example 1 to 7, wherein the conductive layer may be coupled to a reference voltage.

Example 9 may include the subject matter of any one of Example 1 to 8, wherein the plurality of trenches may be coupled to a power supply voltage.

Example 10 may include the subject matter of any one of Example 1 to 8, wherein the plurality of trenches may include a first group and a second group, wherein the first group of trenches may be coupled to a first power supply voltage, and wherein the second group of trenches may be coupled to a second power supply voltage different from the first power supply voltage.

Example 11 may include the subject matter of any one of Example 1 to 10, wherein the conductive layer and the plurality of trenches may be coupled to the redistribution layer.

Example 12 may include the subject matter of any one of Example 1 to 11, further including a package substrate, wherein the bridge substrate and the redistribution layer may be at least partially embedded in the package substrate.

Example 13 may include the subject matter of Example 12, wherein the conductive layer and the plurality of trenches may be coupled to the package substrate through the plurality of first contact pads and the plurality of second contact pads, respectively.

Example 14 may include the subject matter of Example 12 or 13, further comprising a first die and a second die on the package substrate, wherein the bridge substrate and the redistribution layer may form an embedded multi-die interconnect bridge, and wherein the first die and the second die may be coupled through the redistribution layer.

Example 15 may include the subject matter of Example 14, wherein the conductive layer may be coupled to the first die and the second die through the plurality of first contact pads, and wherein each of the plurality of trenches may be coupled to at least one of the first die or the second die through a respective one of the plurality of second contact pads.

Example 16 may include the subject matter of Example 14 or 15, wherein the conductive layer and each of the plurality of trenches may be coupled to at least one of the first die or the second die through the redistribution layer.

Example 17 may include a method of forming a device, the method including providing a bridge substrate and a redistribution layer under a bottom surface of the bridge substrate; forming a plurality of intermediate trenches vertically extending into the bridge substrate from a top surface of the bridge substrate; forming a conductive layer on inner walls of the plurality of intermediate trenches and forming a dielectric layer on the conductive layer; forming conductive fillings into the plurality of intermediate trenches, wherein the conductive fillings may be on the dielectric layer; and forming a plurality of first contact pads and a plurality of second contact pads on the top surface of the bridge substrate, wherein the plurality of first contact pads may be coupled to the conductive layer, and wherein the plurality of second contact pads may be coupled to the conductive fillings in the plurality of intermediate trenches.

Example 18 may include the subject matter of Example 17, further including at least partially embedding the bridge substrate and the redistribution layer in a package substrate, wherein the conductive layer and the conductive fillings may be coupled to the package substrate through the plurality of first contact pads and the plurality of second contact pads, respectively; and arranging a first die and a second die on the package substrate, wherein the first die and the second die may be coupled to the conductive layer through the plurality of first contact pads and each may be coupled to a respective one of the conductive fillings through a corresponding one of the plurality of second contact pads.

Example 19 may include a semiconductor package including a package substrate, a bridge at least partially embedded in the package substrate, a first die and a second die on the package substrate. The bridge may include a bridge substrate and a redistribution layer on a top surface of the bridge substrate. The bridge substrate may include a plurality of trenches extending vertically into the bridge substrate from a bottom surface of the bridge substrate, wherein each trench of the plurality of trenches may include a conductive filling; a conductive layer partially surrounding the plurality of trenches and separated from the plurality of trenches by a dielectric layer; a plurality of first contact pads under the bottom surface of the bridge substrate and coupled to the conductive layer; and a plurality of second contact pads under the bottom surface of the bridge substrate and coupled to the plurality of trenches. The first die and the second die may be coupled to the conductive layer through the plurality of first contact pads. The first die may be coupled to at least a respective one of the plurality of trenches through a corresponding one of the plurality of second contact pads. The second die may be coupled to at least an other respective one of the plurality of trenches through an other corresponding one of the plurality of second contact pads.

Example 20 may include the subject matter of Example 19, wherein the first die and the second die may overlie both the package substrate and the bridge.

In a further example, any one or more of examples 1 to 20 may be combined.

These and other advantages and features of the aspects herein disclosed will be apparent through reference to the above description and the accompanying drawings. Furthermore, it is to be understood that the features of the various aspects described herein are not mutually exclusive and can exist in various combinations and permutations.

It will be understood that any property described herein for a specific device may also hold for any device described herein. It will also be understood that any property described herein for a specific method may hold for any of the methods described herein. Furthermore, it will be understood that for any device or method described herein, not necessarily all the components or operations described will be enclosed in the device or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a bridge substrate comprising:
a plurality of trenches extending vertically into the bridge substrate from a bottom surface of the bridge substrate, wherein each trench of the plurality of trenches comprises a conductive filling;
a conductive layer partially surrounding the plurality of trenches and separated from the plurality of trenches by a dielectric layer;
a plurality of first contact pads under the bottom surface of the bridge substrate and coupled to the conductive layer; and
a plurality of second contact pads under the bottom surface of the bridge substrate and coupled to the conductive fillings of the plurality of trenches; and
a redistribution layer on a top surface of the bridge substrate.

2. The device of claim 1, wherein the plurality of trenches is configured spaced apart from the top surface of the bridge substrate.

3. The device of claim 1, wherein the plurality of trenches extends vertically through the bridge substrate.

4. The device of claim 1, wherein the conductive layer further extends along the bottom surface of the bridge substrate and extends between the plurality of trenches, and wherein the dielectric layer further extends along the conductive layer and extends between the plurality of trenches.

5. The device of claim 1, wherein the dielectric layer comprises a high-k material having a relative permittivity of 20-15000.

6. The device of claim 1, wherein the plurality of first contact pads and the plurality of second contact pads lie in a same plane under the bottom surface of the bridge substrate.

7. The device of claim 1, wherein the conductive layer, the dielectric layer and the conductive fillings of the plurality of trenches form an array of capacitors.

8. The device of claim 1, wherein the conductive layer is coupled to a reference voltage.

9. The device of claim 1, wherein the plurality of trenches is coupled to a power supply voltage.

10. The device of claim 1, wherein the plurality of trenches comprises a first group and a second group, wherein the first group of trenches is coupled to a first power supply voltage, and wherein the second group of trenches is coupled to a second power supply voltage different from the first power supply voltage.

11. The device of claim 1, wherein the conductive layer and the plurality of trenches are coupled to the redistribution layer.

12. The device of claim 1, further comprising a package substrate, wherein the bridge substrate and the redistribution layer are at least partially embedded in the package substrate.

13. The device of claim 12, wherein the conductive layer and the plurality of trenches are coupled to the package substrate through the plurality of first contact pads and the plurality of second contact pads, respectively.

14. The device of claim 12, further comprising a first die and a second die on the package substrate, wherein the bridge substrate and the redistribution layer form an embedded multi-die interconnect bridge, and wherein the first die and the second die are coupled through the redistribution layer.

15. The device of claim 14, wherein the conductive layer is coupled to the first die and the second die through the plurality of first contact pads, and wherein each of the plurality of trenches is coupled to at least one of the first die or the second die through a respective one of the plurality of second contact pads.

16. The device of claim 14, wherein the conductive layer and each of the plurality of trenches are coupled to at least one of the first die or the second die through the redistribution layer.

17. A method comprising:
providing a bridge substrate and a redistribution layer under a bottom surface of the bridge substrate;
forming a plurality of intermediate trenches vertically extending into the bridge substrate from a top surface of the bridge substrate;
forming a conductive layer on inner walls of the plurality of intermediate trenches, and forming a dielectric layer on the conductive layer;
forming conductive fillings into the plurality of intermediate trenches, wherein the conductive fillings are on the dielectric layer;
forming a plurality of first contact pads and a plurality of second contact pads on the top surface of the bridge substrate, wherein the plurality of first contact pads are coupled to the conductive layer, and wherein the plurality of second contact pads are coupled to the conductive fillings in the plurality of intermediate trenches.

18. The method of claim 17, further comprising:
at least partially embedding the bridge substrate and the redistribution layer in a package substrate, wherein the conductive layer and the conductive fillings are coupled to the package substrate through the plurality of first contact pads and the plurality of second contact pads, respectively; and
arranging a first die and a second die on the package substrate, wherein the first die and the second die are coupled to the conductive layer through the plurality of first contact pads and each are coupled to a respective one of the conductive fillings through a corresponding one of the plurality of second contact pads.

19. A semiconductor package comprising:
a package substrate;
a bridge at least partially embedded in the package substrate, the bridge comprising a bridge substrate and a redistribution layer on a top surface of the bridge substrate, wherein the bridge substrate comprises:
a plurality of trenches extending vertically into the bridge substrate from a bottom surface of the bridge substrate, wherein each trench of the plurality of trenches comprises a conductive filling;
a conductive layer partially surrounding the plurality of trenches and separated from the plurality of trenches by a dielectric layer; and
a plurality of first contact pads under the bottom surface of the bridge substrate and coupled to the conductive layer, and a plurality of second contact pads under the bottom surface of the bridge substrate and coupled to the plurality of trenches; and
a first die and a second die on the package substrate, wherein the first die and the second die are coupled to the conductive layer through the plurality of first contact pads, and wherein the first die is coupled to at least a respective one of the plurality of trenches through a corresponding one of the plurality of second contact pads, wherein the second die is coupled to at least an other respective one of the plurality of trenches through an other corresponding one of the plurality of second contact pads.

20. The semiconductor package of claim 19, wherein the first die and the second die overlie both the package substrate and the bridge.
